(19) United States
(12) Patent Application Publication
(10) Pub. No.: US 2026/0088533 A1
(43) Pub. Date: Mar. 26, 2026

(54) ELECTRONIC DEVICE AND MULTI-CONTACT CONNECTOR FOR USE THEREWITH

(71) Applicant: UBICQUIA, INC., FORT LAUDERDALE, FL (US)

(72) Inventors: Travis Ronald Coleman, Sunrise, FL (US); Robert Patrick Fennell, Deerfield Beach, FL (US); Leigh Travis Berry, Fort Lauderdale, FL (US); Eduardo Marabotto, Miami, FL (US)

(21) Appl. No.: 19/334,948

(22) Filed: Sep. 21, 2025

Related U.S. Application Data
(60) Provisional application No. 63/697,579, filed on Sep. 22, 2024.

(51) Int. Cl. H01R 12/71; H01R 12/70; H01R 13/04; H01R 13/52; H05K 5/00

(52) U.S. Cl. CPC H01R 12/712; H01R 12/7047; H01R 12/7052; H01R 13/04; H01R 13/5202; H01R 13/5216; H05K 5/0069

(57) ABSTRACT

A multi-contact connector and an electronic device incorporating same include a base member, first and second sets of electrical contacts, and electrical conduits. The base member defines apertures and includes a first side, a second side, and at least one sidewall. The apertures in the base member are distal from the one or more sidewalls. Electrical contacts of the first set are positioned in the base member apertures such that at least a portion of each electrical contact is exposed on the second side of the base member. Electrical contacts in the second set are positioned on the second side of the base member proximate to the sidewall(s) of the base member. Each electrical conduit couples an electrical contact of the first set to a corresponding electrical contact of the second set to form a pair of coupled contacts. Use of the connector permits a lower profile electronic device.

### CROSS-REFERENCE TO RELATED APPLICATIONS

The present application claims the benefit of and priority upon U.S. Provisional Ser. No. 63/697,579 , which was filed on Sep. 22, 2024, and is incorporated herein by this reference as if fully set forth herein.

### TECHNICAL FIELD

The present disclosure relates generally to multi-contact or multipin connectors that receive electrical power and, more particularly, to an electronic device and a multi-contact connector for use therewith for low profile and aesthetic applications.

### BACKGROUND

Many streetlight luminaires are known to include electrical sockets on their top sides (e.g., for cobra-head style luminaires) or within chambers accessible through hinged or removable doors (e.g., for decorative type luminaires). Such sockets comply with requirements of the National Electrical Manufacturers Association (NEMA) and are typically of the twist-lock variety. The sockets mate with complementary NEMA-compliant plugs of electronic devices, such as photocells, networked lighting controllers, and other Internet of Things (IoT) or Industrial IoT (IIoT) sensors, as well as Wi-Fi access points and small cells, which are intended for mounting to the NEMA-compliant sockets.

Size and weight are important characteristics of streetlight mounted electronic devices for aesthetic and safety purposes. The lower the profile of the electronic device when attached to the streetlight luminaire, the better. The structures and sizes of available NEMA-compliant plugs can limit the minimum profiles of luminaire-mounted electronic devices due to the manner in which the contacts of such plugs are configured to mount to printed circuit boards within the electronic devices.

### SUMMARY

In some embodiments, a multi-contact connector for use in an electronic device includes a base member, a first plurality or set of electrical contacts, a second plurality or set of electrical contacts, and a plurality of electrical conduits. The base member defines a plurality of apertures and includes a first side (e.g., an exterior or outer side), a second side (e.g., an interior or inner side), and at least one sidewall. The first and second sides of the base member may be opposite sides of the base member. The apertures in the base member are distal from the one or more sidewalls. The electrical contacts of the first set are positioned in the apertures in the base member such that at least a portion of each electrical contact of the first set is exposed on the second side of the base member. The electrical contacts in the second set are positioned on the second side of the base member proximate the at least one sidewall of the base member. Each electrical conduit couples an electrical contact of the first set to a corresponding electrical contact of the second set to form a pair of coupled electrical contacts.

In some embodiments, the electrical contacts of the second set are configured to connect to electrical connection points along a periphery of a printed circuit board (PCB) positioned upon the second side of the base member. In some embodiments, one or more pairs of coupled electrical contacts are formed from a single piece of metal (e.g., brass or copper alloy, which may be plated with nickel, zinc, or tin).

In some embodiments, the connector further includes a third set of electrical contacts positioned in one or more additional apertures of the base member in a bent configuration such that a first portion of each electrical contact of the third set is exposed on the first side of the base member and a second portion of each electrical contact of the third set is exposed on the second side of the base member. In this case, the first portion of the electrical contact of the third set is substantially flush with the first side of the base member.

In some embodiments, the connector further includes a sealing element secured to the first side of the base member. In some embodiments, the connector further includes epoxy resin that seals some or all the base member apertures. In other embodiments, the epoxy resin seals portions of the first set of electrical contacts within their associated base member apertures.

In some embodiments, the connector further includes a plurality of screw bosses coupled to the second side of the base member proximate, and optionally coupled to, the at least one sidewall. In some or all those embodiments, the screw bosses and the second set of electrical contacts are configured for alignment with through-holes and electrical contact points on a PCB placed on the second side of the base member.

In some embodiments, an electronic device, such as a lighting controller, computing platform, or an IIoT or IoT sensor, includes a multi-contact connector and a PCB. In such embodiments, the connector includes a base member, a first set of electrical contacts, a second set of electrical contacts, and a plurality of electrical conduits. The base member defines a plurality of apertures and includes a first side, a second side, and at least one sidewall. The first and second sides of the base member may be opposite sides of the base member. The apertures in the base member are distal from the one or more sidewalls and may be located near a center of the base member. The electrical contacts of the first set are positioned in the apertures in the base member such that at least a portion of each electrical contact of the first set is exposed on the second side of the base member. The electrical contacts in the second set are positioned on the second side of the base member proximate the at least one sidewall of the base member. Each electrical conduit couples an electrical contact of the first set to a corresponding electrical contact of the second set to form a pair of coupled electrical contacts. The PCB defines through-holes and is positioned atop the second side of the base member such that each electrical contact of the second set passes through a respective through-hole of the PCB. By configuring the connector as described above, space is opened in the middle of the PCB, providing more flexibility for component arrangement and enabling the profile of the overall electronic device to be reduced.

In some embodiments, the electronic device connector further includes a plurality of screw bosses coupled to the second side of the base member proximate, and optionally coupled to, the at least one sidewall. The connector may also or alternatively include a sealing element secured to the first side of the base member.

In some embodiments, the electronic device includes circuitry on the PCB to provide surge protection, power metering, and/or other functions. Additionally or alternatively, the circuitry on the PCB or on one or more other PCBs coupled to the PCB may implement other functions, including performing alternating current-to-direct current (AC-to-DC) power conversion, data processing, power metering, lighting control, wireless or wired communications, temperature management, tilt sensing, and other functions performed by the electronic device.

In some embodiments, electrical contacts of the second set are configured to connect to electrical connection points along a periphery of the PCB, such as to circuitry near the edge of the PCB. In such embodiments and others, the electrical contacts of the second set may be designed for modularity to connect to different circuitry patterns on different PCBs that may rest on the second side of the connector's base member.

In some embodiments, the PCB positioned on or atop the second side of the base member includes surface mount technology (SMT) components mounted on a surface of the PCB. In some embodiments, the electronic device connector further includes a sealing element secured to the first side of the base member. In some embodiments, each pair, or a pair, of coupled electrical contacts of the electronic device's connector are formed from a single piece of metal. In some embodiments, the electronic device includes a communication module to enable the electronic device to wirelessly communicate with a remote application or server.

In some embodiments, a lighting controller, such as a networked smart lighting controller, includes a multi-contact connector, a PCB, circuitry on the PCB providing surge protection, power metering, or other functions, an AC-to-DC power supply, and lighting control circuitry receiving DC power from the power supply. In such embodiments, the connector includes a base member, a first set of electrical contacts, a second set of electrical contacts, and a plurality of electrical conduits. The base member defines a plurality of apertures and includes a first side, a second side, and at least one sidewall. The first and second sides of the base member may be opposite sides of the base member. The apertures in the base member are distal from the one or more sidewalls and may be located near a center of the base member. The electrical contacts of the first set are positioned in the apertures in the base member such that at least a portion of each electrical contact of the first set is exposed on the second side of the base member. The electrical contacts in the second set are positioned on the second side of the base member proximate the at least one sidewall of the base member. Each electrical conduit couples an electrical contact of the first set to a corresponding electrical contact of the second set to form a pair of coupled electrical contacts. The PCB defines through-holes and is positioned on top of the second side of the base member such that each electrical contact of the second set passes through a respective through-hole of the PCB. By configuring the connector as described above, space is opened in the middle of the PCB, providing more flexibility for component arrangement and enabling the profile of the overall electronic device to be reduced.

In some embodiments, the lighting controller further includes a plurality of screw bosses on the second side of the base member proximate the at least one sidewall of the base member. In some embodiments, alignment of the PCB and circuitry thereon depends on a location of the second set of electrical contacts and locations of the screw bosses.

In some embodiments, the lighting controller may include power metering circuitry and a microcontroller. In some embodiments, electrical contacts of the second set are configured to connect to electrical connection points along a periphery of the PCB, such as to circuitry near the edge of the PCB. Locating electrical connection points along a periphery of the PCB provides more room at the center of the PCB for arranging various components of the circuitry (e.g., power metering circuitry or surge protection circuity) on the PCB. In such embodiments and others, the electrical contacts of the second set may be designed for modularity to connect to different circuitry patterns on different PCBs that may rest on the second side of the connector's base member.

In some embodiments, the connector of the lighting controller further includes a sealing element secured to the first side of the base member. In some embodiments, each pair, or a pair, of coupled electrical contacts of the lighting controller's connector and its or their associated electrical conduit are formed from a single piece of metal (e.g., brass or copper alloy, which may be plated with nickel, zinc, or tin). In some embodiments, the electronic device includes a communication module to enable the lighting controller to wirelessly communicate with a remote application or server.

### BRIEF DESCRIPTION OF THE DRAWINGS

Non-limiting and non-exhaustive embodiments are described with reference to the following drawings, in which like reference numerals refer to like parts throughout the various views, unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings.

FIG. 1 illustrates a bottom view of a multi-contact connector in accordance with exemplary embodiments of the present disclosure.

FIG. 2 illustrates a bottom perspective view of the connector of FIG. 1.

FIG. 3 illustrates a top view of the connector of FIG. 1 in accordance with exemplary embodiments of the present disclosure.

FIG. 4 illustrates a top perspective view of the connector of FIG. 1.

FIG. 5 illustrates a perspective view of an exemplary electronic device incorporating a multi-contact connector as connected to a mating connector on top of a streetlight luminaire in accordance with exemplary embodiments of the present disclosure.

FIG. 6 illustrates a side view of the exemplary electronic device shown in FIG. 5.

FIG. 7 illustrates a side view of the exemplary electronic device as shown in FIGS. 5 and 6 with the device's housing removed and connected to a mating connector on top of an exemplary streetlight luminaire.

FIG. 8 illustrates a side view of the exemplary electronic device as shown in FIGS. 5-7 with the device's housing removed and the electronic device disconnected and positioned above the mating connector of the exemplary streetlight luminaire.

### DETAILED DESCRIPTION

In the following description, certain exemplary embodiments are disclosed to provide an understanding of the subject matter set forth in the appended claims. However, one skilled in the relevant art will recognize that the disclosed embodiments and other embodiments may be practiced without one or more of the methods, components, or materials set forth herein, or with other methods, components, or materials. Additionally, in the present disclosure and the accompanying figures, well-known structures have been omitted or shown and described in reduced detail to avoid unnecessarily obscuring descriptions and illustrations of the disclosed exemplary embodiments.

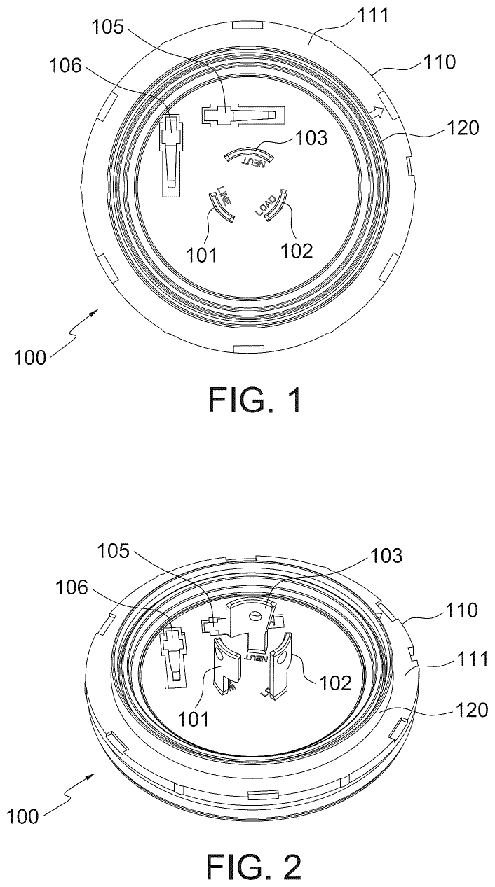

Referring to FIGS. 1-4, a multi-contact connector 100 for use in an electronic device includes a base member 110, a first plurality or set of electrical contacts, a second plurality or set of electrical contacts, and a plurality of electrical conduits 231-233 (e.g., wires, cables, traces, and so forth). The base member 110 defines a plurality of apertures and includes a first side 111 (e.g., an exterior, outer, or bottom side), a second side 112 (e.g., an interior, inner or top side), and at least one sidewall 113. The first and second sides 111, 112 of the base member 110 may be opposite sides of the base member 110, as shown in exemplary form in FIGS. 1-4.

In one exemplary embodiment, the electrical contacts of the first set are configured in a plug arrangement as illustrated in FIGS. 1-4. In such arrangement, each electrical contact of the first set includes a first portion 101-103 and a second portion 201-203. The apertures in the base member 110 are distal from the one or more sidewalls 113 and may be located around a center axis of the base member 110 as illustrated in exemplary form in FIG. 1 (with the apertures being already filled with the first set of electrical contacts and optional resin to mitigate moisture, dust, and other environmental debris penetration). The electrical contacts of the first set are positioned in the apertures in the base member 110 such that the first portion 101-103 of each electrical contact of the first set is exposed on the first side 111 of the base member 110 and the second portion 201-203 of each electrical contact of the first set is exposed on the second side 112 of the base member 110. In one exemplary embodiment, the electrical contacts of the first set are intended to receive AC power from the mating connector of the streetlight luminaire or another external source of AC power.

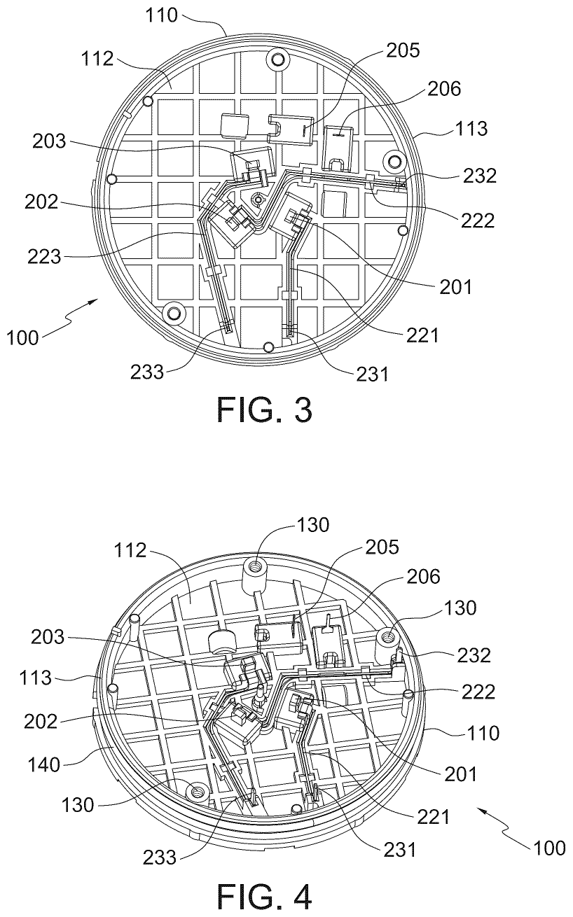

In an alternative exemplary embodiment, the electrical contacts of the first set may be configured in a socket arrangement instead of a plug arrangement. In such a case, the electrical contacts of the first set are positioned in the apertures in the base member 110 such that each electrical contact of the first set is exposed on the second side 112 of the base member 110 only. The exposed portions of the first set of electrical contacts would be similar to the contact portions 201-203 as illustrated in FIGS. 3 and 4.

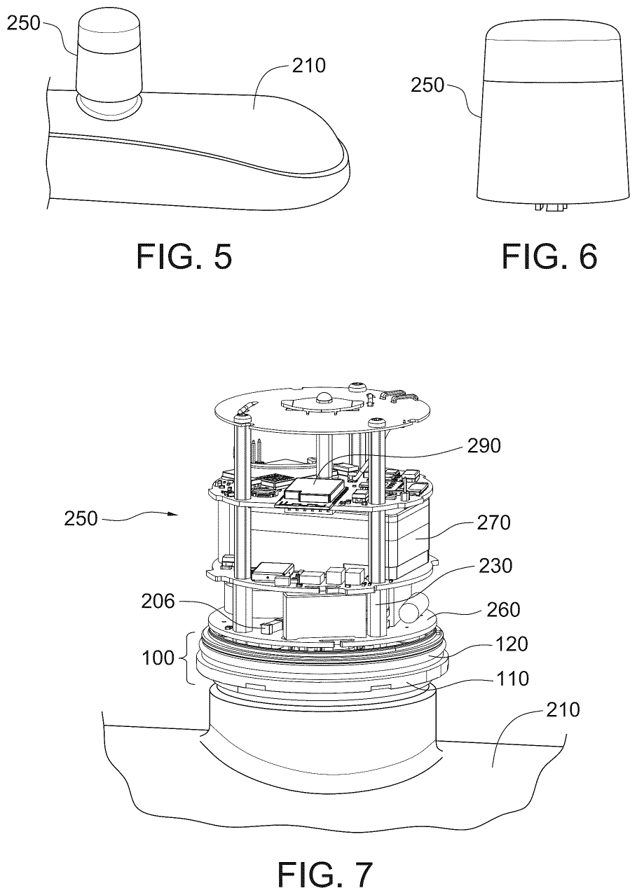

The electrical contacts 231-233 of the second set are positioned on the second side 112 of the base member 110 proximate the at least one sidewall 113 of the base member 110, thereby opening up space for components in the middle portion of a PCB positioned on the base member 110. Each electrical conduit 221-223 couples an electrical contact of the first set to a corresponding electrical contact 231-233 of the second set to form a pair of coupled electrical contacts. The electronic device may be a streetlight-mountable lighting controller, such as the lighting controller 250 illustrated in FIGS. 5-8, or any other streetlight, pole, or connector mounted electronic device in which a low profile multi-contact connector is desired.

Additionally, in some embodiments, the connector 100 may include a third set of electrical contacts positioned in one or more additional apertures of the base member 110 in a bent configuration such that a first portion 105, 106 of each electrical contact of the third set is exposed on the first side 111 of the base member 110 and a second portion 205, 206 of each electrical contact of the third set is exposed on the second side 112 of the base member 110. In this case, the first portion 105, 106 of each electrical contact of the third set is substantially flush with the first side 111 of the base member 110 as illustrated in FIGS. 1 and 2.

The electronic device may be a streetlight-mountable lighting controller, such as the lighting controller 250 illustrated in FIGS. 5-8, or any other streetlight, pole, or connector mounted electronic device in which a low profile multi-contact connector is desired. For example, where the electronic device is a streetlight-mountable lighting controller or other streetlight-mountable electronic device that includes lighting control functionality, the third set of electrical contacts, when included, may be electrical contacts used for providing lighting control signals, such as lighting control signals used in (a) 0-10 Volt analog dimming, (b) pulse-width modulated (PWM) lighting control techniques for light emitting diode (LED) luminaires, or (c) digital lighting control techniques such as in accordance with one or more of the Digital Illumination Interface Alliance's Digital Addressable Lighting Interface (DALI) protocols.

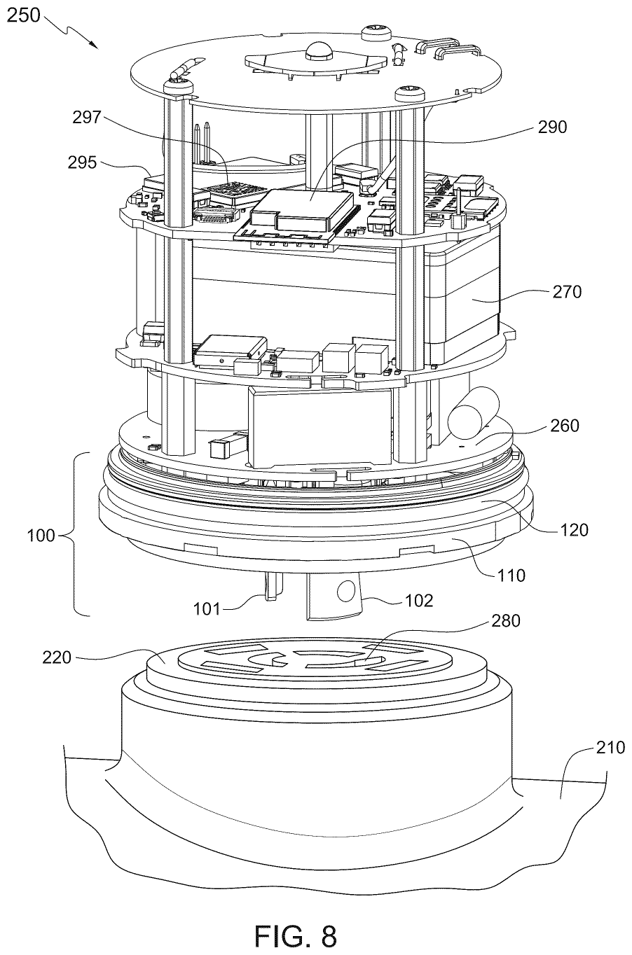

In some embodiments, the electrical contacts 231-233 of the second set are configured to connect to electrical connection points along a periphery of a printed circuit board (PCB) 260, as illustrated in FIGS. 7 and 8, positioned upon the second side 112 of the base member 110. By configuring the second set of electrical contacts 231-233 to connect to electrical connection points along a periphery of the PCB 260, space is opened in the middle of the PCB 260, providing more flexibility for component arrangement and enabling the profile of the overall electronic device that includes the connector 100 to be reduced.

In some embodiments, each pair of coupled electrical contacts and their associated electrical conduit 221-223 may be formed out of a single piece of metal, such as stamped metal or ribbon wire (e.g., made from brass or copper alloy, which may be plated with nickel, zinc, or tin). Use of a single metal component for the pairs of coupled electrical contacts and their respective electrical conduits 221-223 may simply fabrication of the electrical connector 100.

In some embodiments, the electrical connector 100 includes a sealing element 120, which may be a rubber gasket or other sealing material or element. The sealing element 120 keeps moisture and other debris from entering the electronic device that includes the connector 100.

In some embodiments, the connector 100 further includes an epoxy resin sealing the portions 101-103, 201-203 of the first set of electrical contacts within their respective apertures in the base member 110 of the connector 100 and, when the third set of electrical contacts are included, sealing the portions 105-106, 205-206 of the third set of electrical contacts within their respective apertures in the base member 110 of the connector 100. More generally, the connector 100 may include epoxy resin that seals all the apertures in the base member 110 of the connector 100. Between sealing element 120 and the resin-filled apertures, the base member 110 may form a water resistant or watertight chamber that minimizes exposure of the electrical contacts to moisture, dust, and other undesired environmental elements.

In some embodiments, the connector 100 further includes a plurality of screw bosses 130 coupled to the second side 112 of the base member 110 and positioned proximate and inner side of the at least one sidewall 113. The screw bosses 130 may be molded or otherwise formed on the second side 112 of the base member 110. In some embodiments, the screw bosses 130 and the second set of electrical contacts 231-233 are configured for alignment with through-holes and electrical contact points on a PCB 260 placed on the second side 112 of the base member 110. The holes in the PCB 260 that align with the bores on the screw bosses 130 enable the PCB 260 to be secured to the base member 100 with screws (not shown).

In some embodiments with further reference to FIGS. 5-8, an electronic device 250 includes a multi-contact connector, such as the connector 100 discussed above with respect to FIGS. 1-4, and a PCB 260 positioned on top of the second side 112 of the base member 110 such that each electrical contact 231-233 of the second set of electrical contacts passes through a respective through-hole of the PCB 260.

In some embodiments, the PCB 260 includes surge protection, power metering, or other circuitry. The electronic device 250 may also include other circuitry and modules on the PCB 260 or other PCBs that implement or include an AC-to-DC power supply 270, a light sensor 290, lighting control circuitry 295 (e.g., a microcontroller), and a communication module 297 (e.g., an LTE modem). The power supply 270 (and optionally the lighting control circuitry 295 and the communication module 297) receive surge protection from the surge protection circuitry and the lighting control circuitry 295 and the communication module 297 received DC power from the power supply 270.

In some embodiments, screws 230 are used to mount the PCB 260 to the connector's base member 110 via through-holes in the PCB 260, which align with the bores of the screw bosses 130 on the second side 112 of the base member 110. Where the electronic device 250 has a stacked arrangement of PCBs, each screw 230 may be externally threaded at one end (i.e., the end to be threaded into a screw boss 130) and internally threaded at the other end to permit securing by another screw for the layer above it, such as shown in FIGS. 7 and 8.

In some embodiments, the second set of electrical contacts 231-233 is designed for modularity to connect to different circuitry patterns on different PCBs that mate with the second side 112 of the base member 110. In other words, if an updated PCB 260 presents a different circuitry pattern, a corresponding second set of electrical contacts 231-233 and electrical conduits 221-223 can be routed on the second side 112 of the base member 110 to mate with the appropriate contacts points on the updated or revised PCB. The second set of electrical contacts 231-233 can be considered through-board pins that can be placed where necessary to allow modularity for future PCB designs and pin locations near the edge of the PCB. Positioning the second set of electrical contacts 231-233 near the edge of the PCB 260 facilitates having the entire central portion of the top side (and possibly the bottom side) of the PCB 260 available for surface mount components.

In some embodiments, the PCB 260 positioned atop the second side 112 of the base member 110 includes surface mount technology (SMT) components mounted on a surface of the PCB 260. Since the configuration of the connector 100 allows for greater component layout space in the central portion of the PCB 260, the SMT components can be mounted on either side or both sides of the PCB 260.

In some embodiments, as illustrated in FIGS. 5-8, the electronic device 250 is a smart lighting controller including a communication module 297 and a lighting controller 295. The connector 100 of the streetlight controller may be mountable to a mating connector 220 of a streetlight luminaire 210. Where the mating connector 220 is of the socket type, the external portions 101-103 of the electronic device connector's first set of electrical contacts mate into and with respective receptacles 280 of the mating connector 220. In other embodiments, the electronic device 250 can be any electronic apparatus using a multi-contact connector. In some embodiments, the electronic device 250 may use a locking multi-contact connector.

As illustrated in FIG. 7, the exemplary electronic device 250 may be mounted to the streetlight luminaire 210 using a twist-lock NEMA connector, for example. FIG. 8 further illustrates the electronic device 250 just prior to mating with the mating connector 220 of the luminaire 210 so that the exterior portions 101, 102 of two electrical contacts of the electronic device connector's first set of electrical contacts can be seen (the exterior portion 102 of the other electrical contact 103 in the first set is hidden behind exterior connector portion 102).

In the absence of any specific clarification related to its express use in a particular context, where the terms “substantial” or “about” in any grammatical form are used as modifiers in the present disclosure and any appended claims (e.g., to modify a structure, a dimension, a measurement, or some other characteristic), it is understood that the characteristic may vary by up to 30 percent. For example, an electronic device may be described as being mounted “substantially vertical.” In such a case, a device that is mounted exactly vertical is mounted along a “Y” axis and a “X” axis that is normal (i.e., 90 degrees or at right angle) to a plane or line formed by a “Z” axis. Different from the exact precision of the term, “vertical,” the use of “substantially” or “about” to modify the characteristic permits a variance of the particular characteristic by up to 30 percent.

The terms “include” and “comprise” as well as derivatives thereof, in all of their syntactic contexts, are to be construed without limitation in an open, inclusive sense, (e.g., “including, but not limited to”). The term “or,” is inclusive, meaning “and/or. ” The phrases “associated with” and “associated therewith,” as well as derivatives thereof, can be understood as meaning to include, be included within, interconnect with, contain, be contained within, connect to or with, couple to or with, be communicable with, cooperate with, interleave, juxtapose, be proximate to, be bound to or with, have, have a property of, or the like.

Unless the context requires otherwise, throughout the specification and claims which follow, the word “comprise” and variations thereof, such as, “comprises” and “comprising,” are to be construed in an open, inclusive sense (e.g., “including, but not limited to”). Additionally, in this disclosure, the singular shall mean the plural and vice versa, unless expressly stated otherwise.

Reference throughout this specification to “one embodiment” or “an embodiment” or “some embodiments” and variations thereof mean that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content and context clearly dictates otherwise. It should also be noted that the conjunctive terms, “and” and “or” are generally employed in the broadest sense to include “and/or” unless the content and context clearly dictates inclusivity or exclusivity as the case may be. In addition, the composition of “and” and “or” when recited herein as “and/or” is intended to encompass an embodiment that includes all of the associated items and one or more other alternative embodiments that include fewer than all of the associated items.

The various embodiments described above can be combined to provide further embodiments. Aspects of the embodiments can be modified, if necessary to employ concepts of the various patents, application and publications to provide further embodiments.

What is claimed is:

1. A multi-contact connector for use in an electronic device, the connector comprising:
a base member defining a plurality of apertures and including a first side, a second side, and at least one sidewall, the plurality of apertures being distal from the at least one sidewall;
a first set of electrical contacts positioned in the plurality of apertures such that at least a portion of each electrical contact of the first set is exposed on the second side of the base member;
a second set of electrical contacts positioned on the second side of the base member proximate the at least one sidewall; and
a plurality of electrical conduits, wherein each electrical conduit couples an electrical contact of the first set to a corresponding electrical contact of the second set to form a pair of coupled electrical contacts.

2. The connector of claim 1, wherein electrical contacts of the second set are configured to connect to electrical connection points along a periphery of a printed circuit board positioned upon the second side of the base member.

3. The connector of claim 1, wherein the pair of coupled electrical contacts and the associated electrical conduit are formed from a single piece of metal.

4. The connector of claim 1, further comprising:
a third set of electrical contacts positioned in one or more additional apertures of the base member in a bent configuration such that a first portion of each electrical contact of the third set is exposed on the first side of the base member and a second portion of each electrical contact of the third set is exposed on the second side of the base member with the first portion of the electrical contact of the third set being substantially flush with the first side of the base member.

5. The connector of claim 1, further comprising:
epoxy resin that seals the plurality of apertures and the one or more additional apertures.

6. The connector of claim 1, further comprising:
a sealing element secured to the first side of the base member.

7. The connector of claim 1, further comprising:
epoxy resin that seals portions of the first set of electrical contacts within the plurality of apertures.

8. The connector of claim 1, further comprising:
a plurality of screw bosses coupled to the second side of the base member proximate the at least one sidewall.

9. The connector of claim 8, wherein the plurality of screw bosses and the second set of electrical contacts are configured for alignment with through-holes and electrical contact points on a printed circuit board placed on top of the second side of the base member.

10. An electronic device comprising:
a multi-contact connector including:
a base member defining a plurality of apertures and including a first side, a second side, and at least one sidewall, the plurality of apertures being distal from the at least one sidewall;
a first set of electrical contacts positioned in the plurality of apertures such that at least a portion of each electrical contact of the first set is exposed on the second side of the base member;
a second set of electrical contacts positioned on the second side of the base member proximate the at least one sidewall; and
a plurality of electrical conduits, wherein each electrical conduit couples an electrical contact of the first set to a corresponding electrical contact of the second set to form a pair of coupled electrical contacts; and
a printed circuit board defining through-holes and positioned on top of the second side of the base member such that each electrical contact of the second set passes through a respective through-hole of the printed circuit board.

11. The electronic device of claim 10, wherein the connector further includes:
a plurality of screw bosses coupled to the second side of the base member proximate the at least one sidewall.

12. The electronic device of claim 10, wherein electrical contacts of the second set are configured to connect to electrical connection points along a periphery of the printed circuit board.

13. The electronic device of claim 10, wherein electrical contacts of the second set are designed for modularity to connect to different circuitry patterns on different printed circuit boards that mate with the second side of the base member.

14. The electronic device of claim 10, further comprising:
an AC-to-DC power supply.

15. The electronic device of claim 10, wherein the connector further includes a sealing element secured to the first side of the base member.

16. The electronic device of claim 10, wherein the pair of coupled electrical contacts and the associated electrical conduit are formed from a single piece of metal.

17. A lighting controller comprising:
a multi-contact connector including:
a base member defining a plurality of apertures and including a first side, a second side, and at least one sidewall, the plurality of apertures being distal from the at least one sidewall;
a first set of electrical contacts positioned in the plurality of apertures such that at least a portion of each electrical contact of the first set is exposed on the second side of the base member;
a second set of electrical contacts positioned on the second side of the base member proximate the at least one sidewall; and
a plurality of electrical conduits, wherein each electrical conduit couples an electrical contact of the first set to a corresponding electrical contact of the second set to form a pair of coupled electrical contacts;
a printed circuit board defining through-holes and positioned on top of the second side of the base member such that each electrical contact of the second set passes through a respective through-hole of the printed circuit board;
circuitry on the printed circuit board providing surge protection;
an AC-to-DC power supply protected by the surge protection; and
lighting control circuitry that receives DC power from the power supply.

18. The lighting controller of claim 15, further comprising:
a plurality of screw bosses coupled to the second side of the base member proximate the at least one sidewall.

19. The lighting controller of claim 16, wherein the pair of coupled electrical contacts and the associated electrical conduit are formed from a single piece of metal.

20. The lighting controller of claim 16, wherein the connector further includes a sealing element secured to the first side of the base member.
